(19) United States
(12) Patent Application Publication
(10) Pub. No.: US 2022/0151457 A1
(43) Pub. Date: May 19, 2022

(54) USER INTERFACE CONSOLE FOR AN APPLIANCE PROVIDING CLEARANCE FOR AN EDGE CONNECTOR

(71) Applicant: Haier US Appliance Solutions, Inc., Wilmington, DE (US)

(72) Inventor: Michelle Diana Gross, Louisville, KY (US)

(21) Appl. No.: 16/950,230

(22) Filed: Nov. 17, 2020

(51) Int. Cl. A47L 15/42; H05K 1/11; H05K 7/10

(52) U.S. Cl. CPC A47L 15/4274; H05K 1/117; A47L 15/4257; H05K 2201/10265; H05K 2201/09145; H05K 2201/09736; H05K 7/1069

(57) ABSTRACT

A user interface assembly for an appliance includes a user interface console having a first portion and a second portion. The first portion defines a first thickness, the second portion defines a second thickness, wherein the second thickness is greater than the first thickness. The user interface assembly also includes a user interface circuit board secured to the second portion of the user interface console. Further, the user interface assembly includes an edge connector electrically coupled to the user interface circuit board. As such, the second thickness of the second portion of the user interface console provides a clearance between the edge connector and the user interface console. The user interface assembly also includes a wired connection electrically coupled to the edge connector for electrically coupling the user interface circuit board to a controller of the appliance.

### FIELD OF THE INVENTION

The present subject matter relates generally to circuit board for appliances, and more particularly to circuit boards for appliances having a raised console surface that defines a clearance for an edge connector.

### BACKGROUND OF THE INVENTION

Appliances frequently include doors for closing, insulating, concealing, or otherwise providing selective access to cavities or chambers of the appliance. These doors typically include an inner and outer door that are separated by an air gap which may be filled with fiberglass or insulating foam, e.g., for thermal insulation, sound dampening, etc. In order to provide a user with information regarding the appliance operation, e.g., such as a status of an operating cycle or an indication that a cycle is complete, status indicators are often positioned on the outer door of the appliance such that they are visible to a user of the appliance. In addition, or alternatively, appliances, such as dishwasher appliances may include control panels that are integrated into the top of the dishwasher door, e.g., to minimize features on the outer door and provide a clean look.

Notably, however, the sleek appearance of top control dishwasher appliances can have drawbacks. For example, a circuit board that is directly coupled to the control panel typically requires a surface-mount connector for the wiring harness/connection, i.e. on the back side of the circuit board. The surface-mount connector, however, can be costly and may not be ideal for tight clearance areas.

Accordingly, an appliance having an improved circuit board for appliances that can accommodate an edge connector, rather than a surface-mount connector would be advantageous. Thus, the present disclosure is directed to an appliance having a flush-mount circuit board with a raised console surface that defines a clearance for the edge connector.

### BRIEF DESCRIPTION OF THE INVENTION

Aspects and advantages of the invention will be set forth in part in the following description, or may be obvious from the description, or may be learned through practice of the invention.

In an aspect, the present disclosure is directed to a user interface assembly for an appliance. The user interface assembly includes a user interface console having a first portion and a second portion. The first portion defines a first thickness, the second portion defines a second thickness, wherein the second thickness is greater than the first thickness. The user interface assembly also includes a user interface circuit board secured to the second portion of the user interface console. Further, the user interface assembly includes an edge connector electrically coupled to the user interface circuit board. As such, the second thickness of the second portion of the user interface console provides a clearance between the edge connector and the user interface console. The user interface assembly also includes a wired connection electrically coupled to the edge connector for electrically coupling the user interface circuit board to a controller of the appliance.

In another aspect, the present disclosure is directed to a dishwasher appliance. The dishwasher appliance includes a wash tub positioned within a cabinet and defining a wash chamber and a door assembly pivotally mounted to the cabinet to provide selective access to the wash chamber. The door assembly includes a door frame having a top edge and a user interface assembly positioned at the top edge of the door frame. The user interface assembly includes a user interface console having a first portion and a second portion. The first portion defines a first thickness, the second portion defines a second thickness, wherein the second thickness is greater than the first thickness. The user interface assembly also includes a user interface circuit board secured to the second portion of the user interface console. Further, the user interface assembly includes an edge connector electrically coupled to the user interface circuit board. As such, the second thickness of the second portion of the user interface console provides a clearance between the edge connector and the user interface console. The user interface assembly also includes a wired connection electrically coupled to the edge connector for electrically coupling the user interface circuit board to a controller of the appliance.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures.

FIG. 1 provides a perspective view of a dishwasher appliance, including a dishwasher door according to exemplary embodiments of the present disclosure.

FIG. 2 provides a cross-sectional side view of the exemplary dishwashing appliance of FIG. 1.

FIG. 3 provides a close-up perspective view of a control panel of the exemplary dishwasher door of FIG. 1 according to exemplary embodiments of the present disclosure.

FIG. 4 provides a cross-sectional view of one embodiment of a user interface assembly for an appliance according to exemplary embodiments of the present disclosure.

FIG. 5 provides a cross-sectional view of another embodiment of a user interface assembly for an appliance according to exemplary embodiments of the present disclosure.

FIG. 6 provides a cross-sectional view of yet another embodiment of a user interface assembly for an appliance according to exemplary embodiments of the present disclosure.

Repeat use of reference characters in the present specification and drawings is intended to represent the same or analogous features or elements of the present invention.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

As used herein, the terms “first,” “second,” and “third” may be used interchangeably to distinguish one component from another and are not intended to signify location or importance of the individual components. In addition, the term “or” is generally intended to be inclusive (i.e., “A or B” is intended to mean “A or B or both”). Furthermore, as used herein, terms of approximation, such as “approximately,” “substantially,” or “about,” refer to being within a ten percent margin of error.

Generally, the present disclosure is directed to a user interface assembly having a user interface console with a varying thickness. Further, the user interface assembly includes a capacitance touch printed circuit board with electrodes on the front side of the board, which are designed to be mounted flush with the back surface of the console. At least one edge of the circuit board overhangs from a thicker portion of the console, such that an edge connector, such as a RAST connector, can be attached to the edge of the circuit board. The console rear surface may also be recessed for additional clearance to the edge connector.

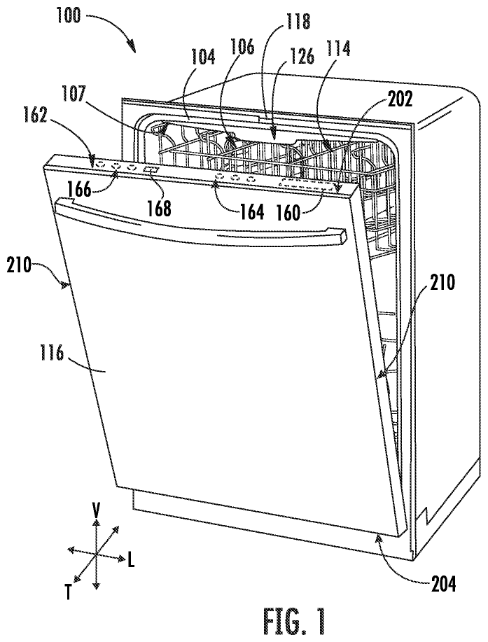

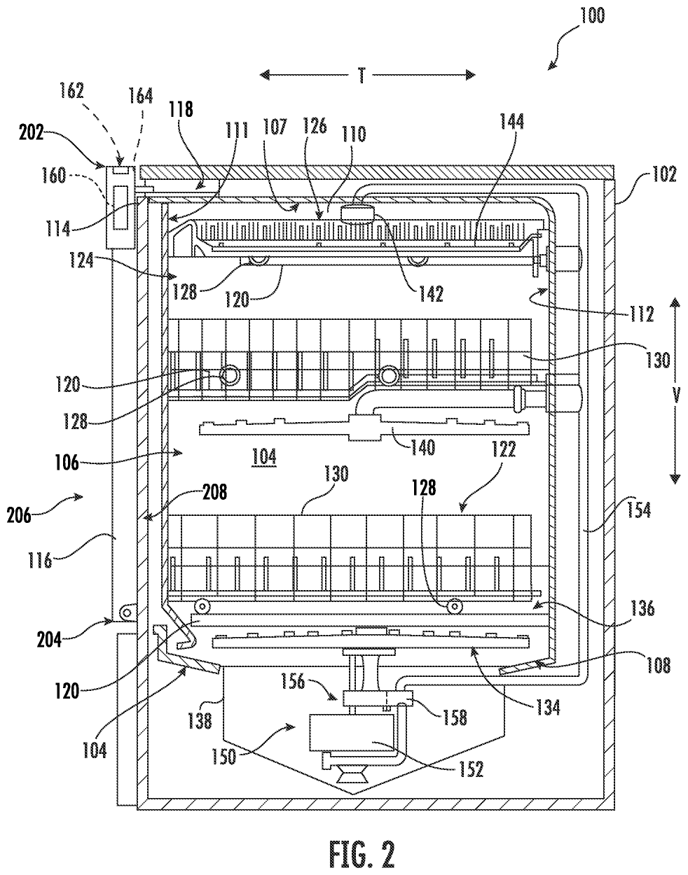

Referring now to the figures, FIGS. 1 and 2 depict an exemplary domestic dishwasher or dishwashing appliance 100 that may be configured in accordance with aspects of the present disclosure. For the particular embodiment of FIGS. 1 and 2, the dishwasher 100 includes a cabinet 102 having a tub 104 therein that defines a wash chamber 106. As shown, tub 104 extends between a top 107 and a bottom 108 along a vertical direction V, between a pair of side walls 110 along a lateral direction L, and between a front side 111 and a rear side 112 along a transverse direction T. Each of the vertical direction V, lateral direction L, and transverse direction T are mutually orthogonal to one another.

The tub 104 includes a front opening 114 and a door 116 hinged at its bottom for movement between a normally closed vertical position (shown in FIG. 2), wherein the wash chamber 106 is sealed shut for washing operation, and a horizontal open position for loading and unloading of articles from the dishwasher 100. According to exemplary embodiments, the dishwasher 100 further includes a door closure mechanism or assembly 118 that is used to lock and unlock door 116 for accessing and sealing wash chamber 106.

As illustrated in FIG. 2, tub side walls 110 may accommodate a plurality of rack assemblies. More specifically, guide rails 120 may be mounted to side walls 110 for supporting a lower rack assembly 122, a middle rack assembly 124, and an upper rack assembly 126. As illustrated, the upper rack assembly 126 is positioned at a top portion of wash chamber 106 above middle rack assembly 124, which is positioned above lower rack assembly 122 along the vertical direction V. Each rack assembly 122, 124, 126 is adapted for movement between an extended loading position (not shown) in which the rack is substantially positioned outside the wash chamber 106, and a retracted position (shown in FIGS. 1 and 2) in which the rack is located inside the wash chamber 106. This is facilitated, for example, by rollers 128 mounted onto rack assemblies 122, 124, 126, respectively. Although a guide rails 120 and rollers 128 are illustrated herein as facilitating movement of the respective rack assemblies 122, 124, 126, it should be appreciated that any suitable sliding mechanism or member may be used according to alternative embodiments.

Some or all of the rack assemblies 122, 124, 126 are fabricated into lattice structures including a plurality of wires or elongated members 130 (for clarity of illustration, not all elongated members making up rack assemblies 122, 124, 126 are shown in FIG. 2). In this regard, rack assemblies 122, 124, 126 are generally configured for supporting articles within wash chamber 106 while allowing a flow of wash fluid to reach and impinge on those articles (e.g., during a cleaning or rinsing cycle). According to another exemplary embodiment, a silverware basket (not shown) may be removably attached to a rack assembly (e.g., lower rack assembly 122) for placement of silverware, utensils, and the like, that are otherwise too small to be accommodated by rack 122.

The dishwasher 100 further includes a plurality of spray assemblies for urging a flow of water or wash fluid onto the articles placed within wash chamber 106. More specifically, as illustrated in FIG. 2, the dishwasher 100 includes a lower spray arm assembly 134 disposed in a lower region 136 of wash chamber 106 and above a sump 138 so as to rotate in relatively close proximity to lower rack assembly 122. Similarly, a mid-level spray arm assembly 140 is located in an upper region of wash chamber 106 and may be located below and in close proximity to middle rack assembly 124. In this regard, mid-level spray arm assembly 140 may generally be configured for urging a flow of wash fluid up through middle rack assembly 124 and upper rack assembly 126. Additionally, an upper spray assembly 142 may be located above upper rack assembly 126 along the vertical direction V. In this manner, the upper spray assembly 142 may be configured for urging or cascading a flow of wash fluid downward over rack assemblies 122, 124, and 126. As further illustrated in FIG. 2, the upper rack assembly 126 may further define an integral spray manifold 144, which is generally configured for urging a flow of wash fluid substantially upward along the vertical direction V through upper rack assembly 126.

The various spray assemblies and manifolds described herein may be part of a fluid distribution system or fluid circulation assembly 150 for circulating water and wash fluid in the tub 104. More specifically, the fluid circulation assembly 150 includes a pump 152 for circulating water or wash fluid (e.g., detergent, water, or rinse aid) in the tub 104. The pump 152 may be located within sump 138 or within a machinery compartment located below sump 138 of tub 104, as generally recognized in the art. Further, the fluid circulation assembly 150 may include one or more fluid conduits or circulation piping for directing water or wash fluid from pump 152 to the various spray assemblies and manifolds. For example, as illustrated in FIG. 2, a primary supply conduit 154 may extend from pump 152, along rear 112 of tub 104 along the vertical direction V to supply wash fluid throughout wash chamber 106.

As illustrated, the primary supply conduit 154 is used to supply wash fluid to one or more spray assemblies (e.g., to mid-level spray arm assembly 140 and upper spray assembly 142). However, it should be appreciated that according to alternative embodiments, any other suitable plumbing configuration may be used to supply wash fluid throughout the various spray manifolds and assemblies described herein. For example, according to another exemplary embodiment, primary supply conduit 154 could be used to provide wash fluid to mid-level spray arm assembly 140 and a dedicated secondary supply conduit (not shown) could be utilized to provide wash fluid to upper spray assembly 142. Other plumbing configurations may be used for providing wash fluid to the various spray devices and manifolds at any location within dishwasher appliance 100.

Each spray arm assembly 134, 140, 142, integral spray manifold 144, or other spray device may include an arrangement of discharge ports or orifices for directing wash fluid received from pump 152 onto dishes or other articles located in wash chamber 106. The arrangement of the discharge ports, also referred to as jets, apertures, or orifices, may provide a rotational force by virtue of wash fluid flowing through the discharge ports. Alternatively, the spray arm assemblies 134, 140, 142 may be motor-driven, or may operate using any other suitable drive mechanism. Spray manifolds and assemblies may also be stationary. The resultant movement of the spray arm assemblies 134, 140, 142 and the spray from fixed manifolds provides coverage of dishes and other dishwasher contents with a washing spray. Other configurations of spray assemblies may be used as well. For example, the dishwasher 100 may have additional spray assemblies for cleaning silverware, for scouring casserole dishes, for spraying pots and pans, for cleaning bottles, etc. One skilled in the art will appreciate that the embodiments discussed herein are used for the purpose of explanation only and are not limitations of the present subject matter.

In operation, the pump 152 draws wash fluid in from sump 138 and pumps it to a diverter assembly 156 (e.g., which may be positioned within sump 138 of dishwasher appliance 100). Diverter assembly 156 may include a diverter disk (not shown) disposed within a diverter chamber 158 for selectively distributing the wash fluid to the spray arm assemblies 134, 140, 142 or other spray manifolds or devices. For example, the diverter disk may have a plurality of apertures that are configured to align with one or more outlet ports (not shown) at the top of diverter chamber 158. In this manner, the diverter disk may be selectively rotated to provide wash fluid to the desired spray device.

The dishwasher 100 is further equipped with a controller 160 to regulate operation of the dishwasher 100. The controller 160 may include one or more memory devices and one or more microprocessors, such as general or special purpose microprocessors operable to execute programming instructions or micro-control code associated with a cleaning cycle. The memory may represent random access memory such as DRAM, or read only memory such as ROM or FLASH. In one embodiment, the processor executes programming instructions stored in memory. The memory may be a separate component from the processor or may be included onboard within the processor. Alternatively, the controller 160 may be constructed without using a microprocessor (e.g., using a combination of discrete analog or digital logic circuitry, such as switches, amplifiers, integrators, comparators, flip-flops, AND gates, and the like) to perform control functionality instead of relying upon software.

The controller 160 may be positioned in a variety of locations throughout dishwasher 100. In the illustrated embodiment, the controller 160 may be located within a control panel area 162 of the door 116, as shown in FIGS. 1 and 2. In such an embodiment, input/output (“I/O”) signals may be routed between the control system and various operational components of the dishwasher 100 along wiring harnesses that may be routed through the bottom of door 116. Typically, the controller 160 includes a user interface panel 164 through which a user may select various operational features and modes and monitor progress of the dishwasher 100. In one embodiment, the user interface 164 may represent a general purpose I/O (“GPIO”) device or functional block. In certain embodiments, the user interface 164 includes input components 166, such as one or more of a variety of electrical, mechanical or electro-mechanical input devices including rotary dials, push buttons, and touch pads. The user interface 164 may further include one or more display components 168, such as a digital display device or one or more indicator light assemblies designed to provide operational feedback to a user. The user interface 164 may be in communication with the controller 160 via one or more signal lines or shared communication busses.

It should be appreciated that the invention is not limited to any particular style, model, or configuration of the dishwasher 100. The exemplary embodiment depicted in FIGS. 1 and 2 is for illustrative purposes only. For example, different locations may be provided for user interface 164, different configurations may be provided for rack assemblies 122, 124, 126, different spray arm assemblies 134, 140, 142 and spray manifold configurations may be used, and other differences may be applied while remaining within the scope of the present subject matter. Moreover, aspects of the present subject matter may be applied to other appliances as well, such as refrigerators, ovens, microwaves, etc.

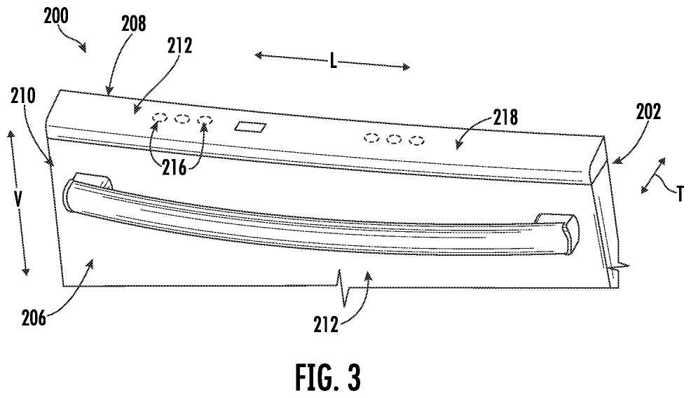

Referring now generally to FIG. 3, a door assembly 200 is described according to exemplary embodiments of the present subject matter. For example, the door assembly 200 may be used as door 116 of the dishwasher 100. Alternatively, the door assembly 200 may be used on any other suitable residential or commercial appliance, such as compactors, disposals, and the like. As described herein, the door assembly 200 may share a coordinate system with the dishwasher 100, e.g., when the door assembly 200 is in the closed position (e.g., as shown in FIG. 2). Specifically, the door assembly 200 may define a vertical direction V, a lateral direction L, and a transverse direction T. Therefore, these directions will also be used herein to refer to features of the door assembly 200 and its various components and sub-assemblies. Referring briefly again to FIGS. 1 and 2, in the normally closed position, the door assembly 200 (illustrated for example as door 116) extends from a top end or top edge 202 to a bottom end or bottom edge 204 along the vertical direction V; from a front end 206 to a rear end 208 along the transverse direction T; and between two lateral ends 210 along the lateral direction L.

Referring still to FIG. 3, the door assembly 200 includes a door frame 210 having a user interface console 212 positioned at a top edge 202 of the door frame 210. Thus, e.g., the user interface console 212 may be partially hidden below a countertop when the dishwasher 100 is installed below the countertop and door 116 (e.g., door assembly 200) is closed. Accordingly, the dishwasher 100 may be referred to as a “top control dishwasher appliance.” However, it should be appreciated that aspects of the present subject matter may be used with dishwasher appliances having other configurations or any other suitable appliance. The user interface console 212 may also be positioned on the door 106 such that a user can engage, e.g., touch, the user interface console 212. Thus, the user can activate/deactivate various cycles of the dishwasher 100 using user interface console 212.

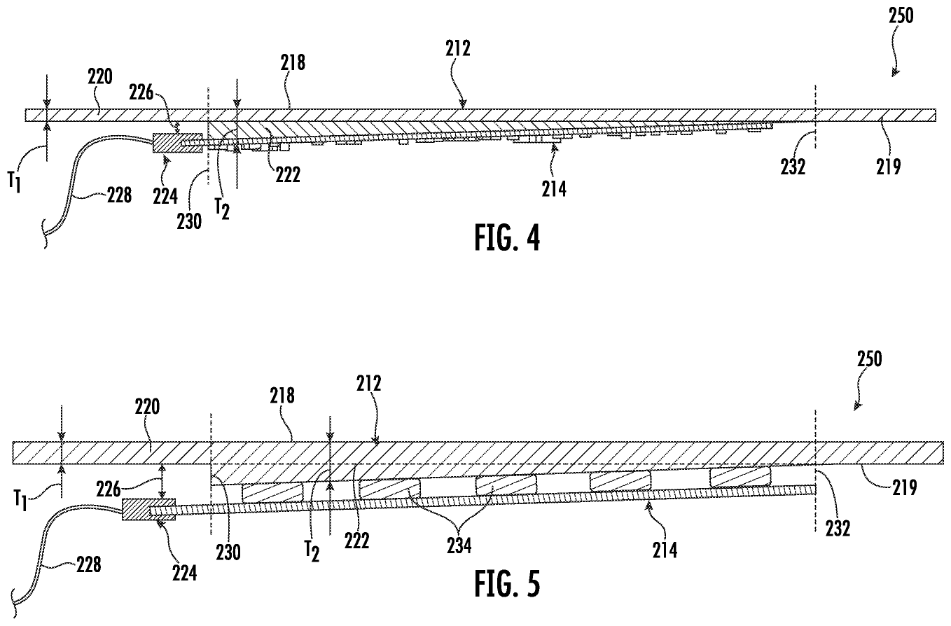

More specifically, according to the embodiment illustrated in FIG. 3, the user interface console 212 may include one or more touch buttons 216 that are mounted to a user interface board 214 (FIGS. 4-6) and are operable to detect user inputs on the user interface console 212. For example, the touch buttons 216 may be configured for triggering when a user touches a top or exterior surface 218 of the user interface console 212. In particular, the touch buttons 216 may be capacitive sensors that can detect when a finger or another conductive material with a dielectric different than air contacts or approaches the user interface console 212. Thus, when a user touches the top surface 218 of the user interface console 212 adjacent one of sensors 216, such sensor 216 triggers and, e.g., signals a controller (e.g., controller 160). In such a manner, operations of the dishwasher 100 can be initiated and controlled. The sensors 216 may be distributed laterally on the user interface board 214 below user the interface console 212. It should be understood that other any suitable number, type, and position of sensors 216 may be used while remaining within the scope of the present subject matter. Indeed, any suitable number, type, and configuration of touch buttons 216 may be used while remaining within the scope of the present subject matter. Furthermore, the exterior surface 218 of the user interface console 212 may have any suitable shape or configuration. For example, in an embodiment, the exterior surface 218 of the user interface console 212 may be arcuate. In alternative embodiments, the exterior surface 218 of the user interface console 212 may be flat.

Referring now to FIGS. 4-6, various cross-sectional views of different embodiments of a user interface assembly 250 of the dishwasher 100 are illustrated. In particular, as shown, the user interface assembly 250 includes the user interface console 212 described herein, as well as the user interface circuit board 214. As an example, in an embodiment, the user interface circuit board 214 as described herein may be a printed circuit board that is positioned within door frame 210. As such, the user interface board 214 may include or be operably coupled to the touch buttons 216 (e.g., or user inputs 166) for receiving user input, providing user notifications, or illuminating to indicate cycle or operating status.

Still referring to FIGS. 4-6, the user interface console 212 includes a first portion 220 and a second portion 222. Furthermore, the first portion 220 defines a first thickness T₁ and the second portion 222 defines a second thickness T₂. Moreover, as shown, the second thickness T₂ is greater than the first thickness T₁. Thus, as generally shown in FIGS. 4-6, the user interface circuit board 214 is secured to the second portion 222 of the user interface console 212. More specifically, as shown, the user interface circuit board 214 is secured to an interior surface 219 of the user interface console 212. In such embodiments, the user interface circuit board 214 may be secured to the second portion 222 of the user interface console 212 using any suitable means, such as via snaps, screws, springs, adhesives, or any other suitable fastening means.

Further, as shown, the user interface assembly 250 of the user interface console 212 includes an edge connector 224 electrically coupled to the user interface circuit board 214. As such, the second thickness T₂ of the second portion 222 of the user interface console 212 provides a clearance 226 between the edge connector 224 and the user interface console 212. The user interface assembly 250 also includes a wired connection 228 electrically coupled to the edge connector 224 for electrically coupling the user interface circuit board 214 to a controller (e.g. controller 160) of the appliance 100.

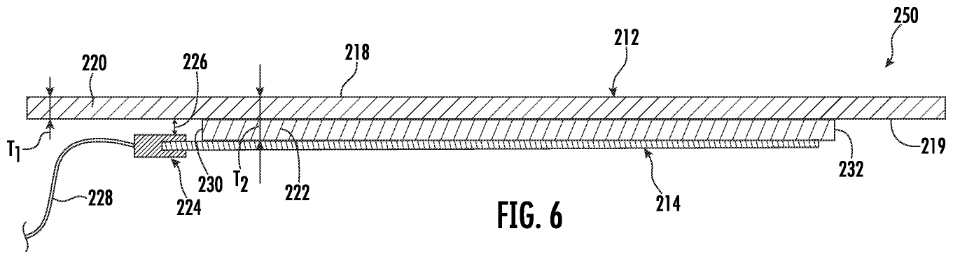

Referring particularly to FIGS. 4 and 5, the second thickness T₂ of the second portion 222 may vary throughout the second portion 222. For example, as shown in FIGS. 4 and 5, the second thickness T₂ of the second portion 222 tapers from a first end 230 to a second end 232 of the second portion 222. Thus, as shown, the first end 230 of the second portion 222, which protrudes from the user interface console 212, provides the necessary clearance 226 for the edge connector 224. In an alternative embodiment, as shown in FIG. 6, the second thickness T₂ of the second portion 222 may constant throughout the second portion 222, e.g. from the first end 230 to the second end 232 of the second section 222.

In further embodiments, as shown in FIG. 4, the first and second portions 220, 222 of the user interface console 212 may be integral with each other. In other words, the first and second portions 220, 222 of the user interface console 212 may be a unitary part. Alternatively, in certain embodiments, as shown in FIGS. 5 and 6, the first and second portions 220, 222 may be separate components secured together to form the user interface console 212.

In still further embodiments, as shown in FIGS. 4 and 6, the user interface circuit board 214 may be flush-mounted directly to the user interface console 212. In alternative embodiments, as shown particularly to FIG. 5, the user interface assembly 250 may include one or more spacers 234 secured between the user interface console 212 and the user interface circuit board 214. In such embodiments, the spacer(s) 234 may be, for example, foam pads or springs. Thus, the addition of the spacer(s) 234 increases the clearance 226 of the edge connection 224 as needed and also provides further flexibility to the assembly 250.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A user interface assembly for an appliance, the user interface assembly comprising:
a user interface console comprising a first portion and a second portion, the first portion defining a first thickness, the second portion defining a second thickness, the second thickness being greater than the first thickness;
a user interface circuit board secured to the second portion of the user interface console;
an edge connector electrically coupled to the user interface circuit board, wherein the second thickness of the second portion of the user interface console provides a clearance between the edge connector and the user interface console; and
a wired connection electrically coupled to the edge connector for electrically coupling the user interface circuit board to a controller of the appliance.

2. The user interface assembly of claim 1, wherein the second thickness of the second portion is constant throughout the second portion.

3. The user interface assembly of claim 1, wherein the second thickness of the second portion varies throughout the second portion.

4. The user interface assembly of claim 3, wherein the second thickness of the second portion tapers from a first end to a second end of the second portion.

5. The user interface assembly of claim 1, wherein the first and second portions are integral with each other.

6. The user interface assembly of claim 1, wherein the first and second portions are separate components secured together to form the user interface console.

7. The user interface assembly of claim 1, further comprising one or more spacers secured between the user interface console and the user interface circuit board.

8. The user interface assembly of claim 1, wherein the one or more spacers comprises at least one of foam pads or springs.

9. The user interface assembly of claim 1, wherein the appliance comprises at least one of a dishwasher appliance, a disposal appliance, or a compactor appliance.

10. The user interface assembly of claim 1, wherein the user interface circuit board is positioned at a top edge of a door frame of the appliance.

11. The user interface assembly of claim 1, wherein user interface console defines an exterior surface and an interior surface, the user interface circuit board being secured to the interior surface, the exterior surface comprising a plurality of buttons for engagement by a user.

12. The user interface assembly of claim 11, wherein the exterior surface of the user interface console is arcuate.

13. The user interface assembly of claim 11, wherein the exterior surface of the user interface console is flat.

14. A dishwasher appliance, comprising:
a wash tub positioned within a cabinet and defining a wash chamber; and
a door assembly pivotally mounted to the cabinet to provide selective access to the wash chamber, the door assembly comprising:
a door frame having a top edge;
a user interface assembly positioned at the top edge of the door frame, the user interface assembly comprising:
a user interface console comprising a first portion and a second portion, the first portion defining a first thickness, the second portion defining a second thickness, the second thickness being greater than the first thickness;
a user interface circuit board secured to the second portion of the user interface console;
an edge connector electrically coupled to the user interface circuit board, wherein the second thickness of the second portion of the user interface console provides a clearance between the edge connector and the user interface console; and
a wired connection electrically coupled to the edge connector for electrically coupling the user interface circuit board to a controller of the appliance.

15. The dishwasher appliance of claim 14, wherein the second thickness of the second portion is constant throughout the second portion.

16. The dishwasher appliance of claim 14, wherein the second thickness of the second portion varies throughout the second portion.

17. The dishwasher appliance of claim 16, wherein the second thickness of the second portion tapers from a first end to a second end of the second portion.

18. The dishwasher appliance of claim 14, wherein the first and second portions are integral with each other.

19. The dishwasher appliance of claim 14, wherein the user interface assembly further comprises one or more spacers secured between the user interface console and the user interface circuit board.

20. The dishwasher appliance of claim 19, wherein the one or more spacers comprises at least one of foam pads or springs.
